(19) United States
(12) Patent Application Publication
(10) Pub. No.: US 2026/0206382 A1
(43) Pub. Date: Jul. 16, 2026

(54) MICROLEDS WITH NANOPATTERNED SURFACE

(71) Applicant: Lumileds LLC, San Jose, CA (US)

(72) Inventors: Antonio Lopez Julia, Eindhoven (NL); Erik William Young, San Jose, CA (US)

(21) Appl. No.: 19/137,983

(22) PCT Filed: Dec. 12, 2023
(86) PCT No.: PCT/US2023/083606

§ 371 Date: Jun. 11, 2025

Related U.S. Application Data
(60) Provisional application No. 63/432,935, filed on Dec. 15, 2022.

(51) Int. Cl. H10H 20/80; H10H 20/819; H10H 20/841

(52) U.S. Cl. CPC H10H 20/872; H10H 20/819; H10H 20/841

(57) ABSTRACT

An illumination device is provided to incorporate light extraction features in a micro-light emitting diode (microLED). The microLED contains a semiconductor stack that includes n-type and p-type semiconductors, and an active region therebetween. The microLED has an emitting surface from which light generated by the active region exits the microLED. The emitting surface has nanoscale patterned sapphire substrate (nanoPSS) features therein. The nanoPSS features have periodic frustoconical shapes each having a pitch of about 200 nm to about 500 nm, a height of about 200 nm P to about 500 nm, and a spacing of about 20%. Metal sidewalls extend from the emitting surface to form a trench in which the microLED is disposed. The metal sidewalls extend at a trench angle less than about 9% with respect to a normal to the emitting surface and electrically contact the n-type semiconductor.

### PRIORITY CLAIM

This application claims the benefit of priority to United States Provisional Patent Application Ser. No. 63/432,935, filed Dec. 15, 2022, which is incorporated herein by reference in its entirety.

### FIELD OF THE DISCLOSURE

The present disclosure relates to microlight-emitting diodes (microLEDs). In particular, embodiments are directed to light extraction in microLEDs.

### BACKGROUND OF THE DISCLOSURE

There is ongoing effort to improve microLEDs. In particular, it is desirable to improve light extraction efficiency as well as increasing angular emission.

### BRIEF DESCRIPTION OF THE DRAWINGS

FIG. 1 shows an illumination apparatus, in accordance with some examples.

FIG. 2A illustrates a monolithic LED pixel array, in accordance with some examples.

FIG. 2B illustrates a single pixel of the monolithic LED pixel array of FIG. 2A, in accordance with some examples.

FIG. 2C illustrates an alternative single pixel of the monolithic LED pixel array of FIG. 2A, in accordance with some examples.

FIG. 3A illustrates a single pixel of the monolithic LED pixel array of FIG. 2A, in accordance with some examples.

FIG. 3B illustrates angular far-field radiation of microscale patterned sapphire substrate (microPSS) and nanoPSS of the monolithic LED pixel array of FIG. 3A, in accordance with some examples.

FIG. 4 illustrates far-field angular emission response, in accordance with some examples.

FIG. 5 illustrates simulated extraction efficiency (ExE) for various nanoPSS designs, in accordance with some examples.

FIG. 6 illustrates simulated forward emission gain for various nanoPSS designs, in accordance with some examples.

FIG. 7 illustrates an example of an electronic device in accordance with some embodiments.

FIG. 8 illustrates an example lighting system, according to some embodiments.

FIG. 9 shows a block diagram of an example of a system, according to some embodiments.

FIG. 10 illustrates an example hardware arrangement for implementing the above disclosed subject matter, according to some embodiments.

FIG. 11 illustrates an example method of fabricating an LED device, according to some embodiments.

### DETAILED DESCRIPTION

An illumination device and method of fabricating an illumination device are provided to incorporate light extraction features in a micro-light emitting diode (microLED). The emitting surface of the microLED has nanoscale patterned sapphire substrate (nanoPSS) features therein. The features are in the surface of the semiconductor layer and/or a transparent film on the semiconductor layer.

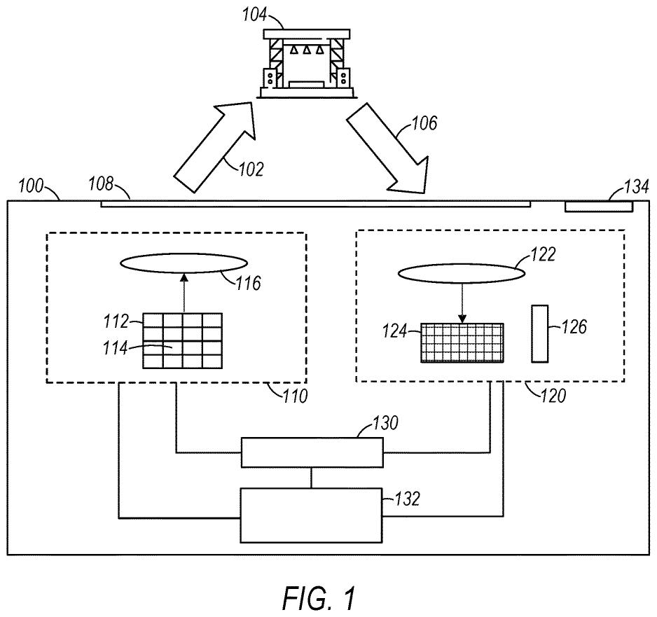

FIG. 1 shows an illumination apparatus 100, in accordance with some examples. The illumination apparatus 100 may be, for example, a smart phone or standalone camera that contains an adaptive LED light source. The illumination apparatus 100 may include both a light source 110 and a camera 120. The camera 120 may capture an image of a scene 104 during an exposure duration of the camera 120, whether or not the scene 104 is illuminated by the light source 110. A processor 130 may be used to control various functions of the light source 110 and the camera 120, including whether or not a shutter is open in an opening 108 of a housing of the illumination apparatus 100.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The illumination apparatus 100 may include one or more LED arrays 112. Each of the one or more LED arrays 112 may include a plurality of LEDs 114 that may produce light during at least a portion of the exposure duration of the camera 120. Each of the one or more LED arrays 112 may contain segmented LEDs 114 in which the LEDs 114 are divided into a grid of light emitting areas (the LEDs 114) and non-light emitting areas (between the LEDs 114). In some embodiments, the effect of the non-light emitting areas on the image captured using the one or more LED arrays 112 may be compensated for by moving the one or more LED arrays 112 and/or at least one lens 116 using one or more actuators during the exposure duration of the scene 104 to shift the LEDs 114 slightly to illuminate the areas of the scene 104 that would be subject to the non-light emitting areas.

Each of the LEDs 114 may be formed using one or more inorganic semiconductor materials (e.g., binary compounds such as gallium arsenide (GaAs) or gallium nitride (GaN), ternary compounds such as aluminum gallium arsenide (AlGaAs), quaternary compounds such as indium gallium phosphide (InGaAsP)), or other suitable materials. The LEDs 114 are typically either III-V materials (defined by columns of the Periodic Table) or II-VI materials. Each of the LEDs 114 may emit light in the visible spectrum (about 400 nm to about 780 nm) or may also emit light in the infrared spectrum (above about 780 nm). In some embodiments, one or more other layers, such as a phosphor layer may be disposed on each of the one or more LED arrays 112 to convert the light from the LEDs 114 into white (or another color) light. LEDs 114 in a particular LED array 112 that emit light in the infrared spectrum may be, for example, interspersed with LEDs 114 may emit light in the visible spectrum, or each type of LED (visible emitter/infrared emitter) may be disposed on different sections of the particular LED array 112. Alternatively, each LED array 112 may only emit light in either the visible spectrum or the infrared spectrum; separate (one or more) LED arrays may be used to emit light in the infrared spectrum, each of the individual LED array 112, LEDs 114 and/or LED segments controllable by the processor 130.

Each of the one or more LED arrays 112 may be, for example, micro-LED array, the latter of which includes thousands to millions of microscopic LEDs 114 that may emit light and that may be individually controlled or controlled in groups of pixels (e.g., 5×5 groups of pixels). The microLEDs are small (e.g., <0.01 mm on a side) and may provide monochromatic or multi-chromatic light, typically red, green, or blue using inorganic semiconductor material such as that indicated above.

The light source 110 may include at least one lens 116 and/or other optical elements such as reflectors. The lens 116 and/or other optical elements may direct the light emitted by the one or more LED arrays 112 toward the scene 104 as illumination 102.

The camera 120 may sense light at least the wavelength or wavelengths emitted by the one or more LED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a multi-pixel sensor 124 (also referred to as a light sensor) to form an image of the scene 104 on the multi-pixel sensor 124.

The processor 130 may receive a data signal that represents the image of the scene 104. The processor 130 may additionally control and drive the LEDs 114 in the one or more LED arrays 112 via one or more drivers 132. For example, the processor 130 may optionally control one or more LEDs 114 in the one or more LED arrays 112 independent of another one or more LEDs 114 in the one or more LED arrays 112, so as to illuminate the scene in a specified manner.

In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), and may further sense the ambient light and/or variations/flicker in the ambient light in addition to reception of the reflected light from the LEDs 114. The multi-pixel sensor 124 of the camera 120 may be of higher resolution than the sensors of the one or more detectors 126 to obtain an image of the scene with a desired resolution. The sensors of the one or more detectors 126 may have one or more segments (that are able to sense the same wavelength/range of wavelengths or different wavelength/range of wavelengths), similar to the LED arrays 112. In some embodiments, if multiple detectors are used, one or more of the detectors may detect visible wavelengths and one or more of the detectors may detect infrared wavelengths; like the one or more LED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs—for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated version of the light source 110 and camera 120.

The LEDs 114 may be driven using a direct current (DC) driver or pulse width modulation (PWM). Using DC driving may encounter color differences if the segmented one or more LED arrays 112 is driven at different current densities, while PWM driving may generate artifacts due to ambient lighting conditions. The flicker sensor, if present, may sense the variation of artificial lighting at the wall current frequency or electronic ballasts frequencies (e.g., 50 Hz or 60 Hz or an integral multiple thereof), in addition to the phase of the flicker. The camera sensor is then tuned to an integration time of an integral multiple of the time period (1/f) or triggered at the phase where the illumination changes most slowly (minimum or maximum intensity, with the maximum intensity preferred for signal-to-noise ratio considerations). The LEDs 114 may be driven using a PWM whose phase shift varies between LEDs 114 to reduce potential current surge issues. As shown, one or more drivers 132 may be used to drive the LEDs 114 in the one or more LED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

As above, the light source 110 of FIG. 1 may be an adaptive flash that contains individually addressable LED segments to allow selective illumination of the scene 104. For array sizes larger than 3×3 matrices, the LED segments may be combined with an integrated driver to allow the function of individual addressability and obtain the small form factor desired for mobile devices without creating issues in layout of the semiconductor layers used to create the integrated devices.

As indicated above, the illumination apparatus 100 shown in FIG. 1, microLEDs can be used to form different types of displays, LED matrices and light engines including automotive adaptive headlights, augmented-, virtual-, mix-reality (AR/VR/MR) headsets, smart glasses and displays for mobile phones, smart watches, monitors and TVs. The individual LED pixels in these architectures may, as above, have an area of few square millimeters down to few square micrometers depending on the matrix or display size and pixel-per-inch requirements. One common approach is to create a monolithic array of LED pixels on an epitaxial wafer and later transfer and hybridize the LED arrays to a backplane to allow individual control of the pixels, as described in more detail below.

MicroLEDs may be formed by combining n- and p-type semiconductors (e.g., III-V semiconductors above) on a substrate of silicon, sapphire aluminum oxide (Al₂O₃) or silicon carbide (SiC), among others. In particular, various layers are deposited and processed on the substrate during fabrication of the microLED. The surface of the substrate may be pretreated to anneal, etch, polish, etc. the surface prior to deposition of the various layers.

In general, the various LED layers may be fabricated using epitaxial semiconductor deposition (e.g., by physical or chemical vapor deposition) to deposit one or more semiconductor layers on a substrate, metal deposition (e.g., by sputtering), oxide growth or deposition, as well as etching, liftoff, and cleaning, among other operations. In some aspects, the growth/deposition substrate may be removed from the LED structure after fabrication and after connection to contacts on a backplane. The connection may be via metal bonding such as via wire or ball bonding. The backplane may be a printed circuit board or wafer containing integrated circuits (ICs), such as a CMOS IC wafer.

The semiconductor deposition operations may be used to create an LED with an active region in which electron-hole recombination occurs and the light from the LED is generated. The active region may be, for example, one or more quantum wells. Metal contacts may be used to provide current to the n- and p-type semiconductors from the ICs (such as drivers) of the backplane on which the LED is disposed. Methods of depositing materials, layers, and thin films may include, for example: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

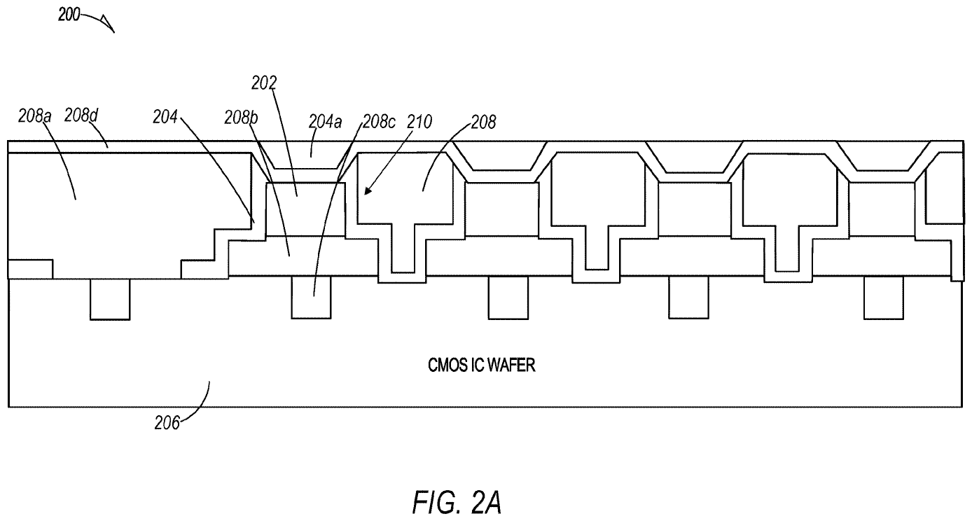

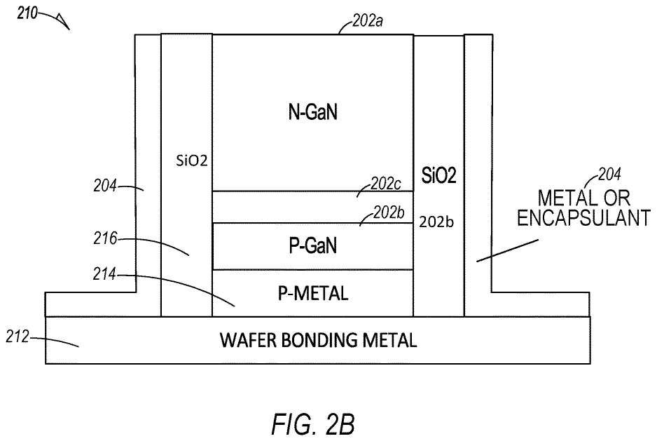

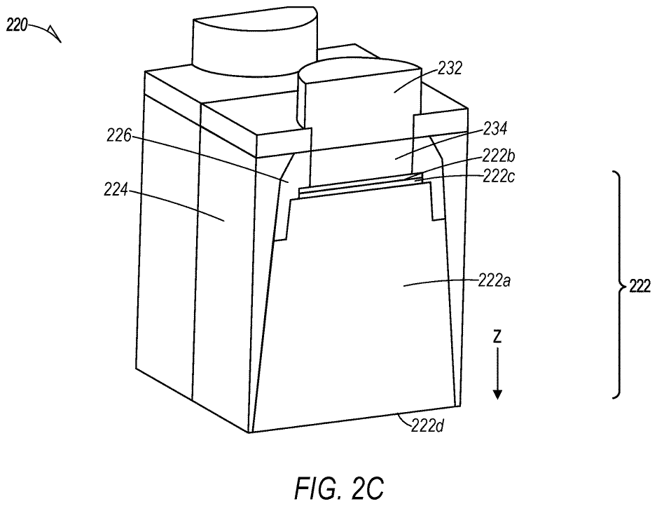

Multiple LEDs may be disposed on the backplane to form a monolithic array. FIG. 2A illustrates a monolithic LED pixel array, in accordance with some examples. FIG. 2B illustrates a single pixel of the monolithic LED pixel array of FIG. 2A, in accordance with some examples. As shown in the monolithic LED pixel array 200 of FIG. 2A, contains pixels 210 each having a sidewall and a semiconductor stack 202 (shown as a mesa structure). A dielectric material 204 surrounds the sidewall of each of the pixels 210, and n-contact material 208 is positioned between adjacent pixels on the dielectric material 204. A common cathode 208a is in electrical contact with the n-type layer of the semiconductor stack 202 and the n-contact material 208. An anode 208b is in contact with each p-type layer of the semiconductor stack 202 and a corresponding contact 208c of a backplane 206. The common cathode 208a is in contact with a contact 208c of the backplane 206. An upper edge of each semiconductor stack 202 may be offset from an upper edge of the n-contact material 208 and common cathode 208a.

Another dielectric material 204a may be opposite the n-type layers of the semiconductor stack 202 and portions of the dielectric material 204. The n-contact material 208 may act as reflective sidewalls adjacent to the semiconductor stack 202. A current spreading layer 208d may contact the n-type layers of the semiconductor stack 202.

As shown in more detail in FIG. 2B, in some aspects, the semiconductor stack 202 of the LED may be formed from GaN. In particular, the semiconductor stack 202 may have a height H and a lateral distance D and may include an active region 202c sandwiched between n-type semiconductor 202a and p-type semiconductor 202b. In some embodiments, the metal side-contacts 216 may be coupled to the n-type semiconductor 202a to drive the n-type semiconductor 202a and, while a metal contact (p-metal 214) is coupled to the p-type semiconductor 202b. The metal side-contacts 216 may be isolated from the p-type semiconductor 202b and the active region 202c by an oxide layer 216. The oxide layer 216 may be formed, for example, by silicon oxide. Wafer bonding metal 212 may be configured to provide contact to the p-metal 214 and metal side-contacts 216. The p-metal 214 and metal side-contacts 216 may be formed from aluminum or other material(s) substantially reflective (e.g., greater than about 99% reflectivity at a normal angle of incidence) to light emitted by the active region 202c. The p-metal 214 and metal side-contacts 216 may be formed from the same metal or different metals. In these architectures, as above the original substrate (e.g., Sapphire, Silicon) may be removed (e.g., by liftoff) after the LED array is integrated with a backplane 206 (that contains a driver and controller, among others) from the opposite side of the pixels 210 as the backplane 206. This offers multiple advantages such as enhanced light extraction and beam profiling. Although the p-metal 214 is shown in FIG. 2B as being the same width as the various layers of the semiconductor stack 202, in other aspects, the p-metal 214 may be larger than the various layers of the semiconductor stack 202 (which may permit contact between the p-metal 214 and the p-type semiconductor 202b).

FIG. 2C illustrates an alternative single pixel of the monolithic LED pixel array of FIG. 2A, in accordance with some examples. The materials of the various layers in FIG. 2C may be the same as those in FIG. 2B. As shown in FIG. 2C, the pixel 220 may include a semiconductor 222 with an active region 222c sandwiched between n-type semiconductor 222a and p-type semiconductor 222 b. Metal side-contacts 224 may be coupled to the n-type semiconductor 222a to drive the n-type semiconductor 222a and, while a metal contact (p-metal 234) is coupled to the p-type semiconductor 222b. The metal side-contacts 224 may be isolated from the p-type semiconductor 222b and the active region 222c by an oxide layer 226. Wafer bonding metal 232 may be configured to provide contact to the p-metal 234. Unlike the pixel 210 in FIG. 2B, the pixel 220 in FIG. 2C may have sidewalls that are angled with respect to the growth direction (shown as the z direction in FIG. 2C and which is perpendicular to the emitting surface 222d of the n-type semiconductor 222a). More details about forming the various layers may be found in U.S. patent application Ser. No. 17/193,017, herein incorporated by reference in its entirety.

One approach to remove a Sapphire substrate on which the GaN-based pixels 210 are fabricated is by a laser lift-off (LLO) process in which a laser beam (UV laser in the case of Sapphire substrate) is used to detach the substrate from the epitaxial layers forming the LED. In large emitters, the substrate may be patterned with micron-scale features (i.e., features on the order of microns). In such a case, the exposed GaN surface of the LED (pixel 210) may be textured after LLO for example, which facilitates light extraction from the pixel 210. In microLEDs, however, this is not possible since the patterned sapphire substrate (PSS) features dimensions are too large relative to the pixel size (which is less than a micron). A discussion of formation of a PSS may be found in U.S. Pat. No. 11,264,530, herein incorporated by reference in its entirety.

Shrinking the size of micron-scale features to nano-scale features enables both fabrication and performance advantages on light emission. Such nano-patterning may be particularly advantageous for small pixel sizes with limited constraints to shape the pixel side wall to facilitate light extraction as small pixel emitters with planar extraction surfaces may suffer from poor extraction efficiency and wide angular radiation profiles. Simulations show that nano-patterned structures on the emitting surface resulting from PSS can offer greater than about 25% flux gain for systems with a collection cone angle of about 45° compared with an unpatterned emitting surface. An unpatterned emitting surface may lead to poor ExE and unfavorable wide angular radiation emission, which is particularly the case of small pixel sizes with relatively steep trench sidewall angles, as shown in the pixel 220 from FIG. 2C. Note that as indicated, the trench extends along at least the height of the semiconductor 222 and maintains a relatively constant (within fabrication limits) angle.

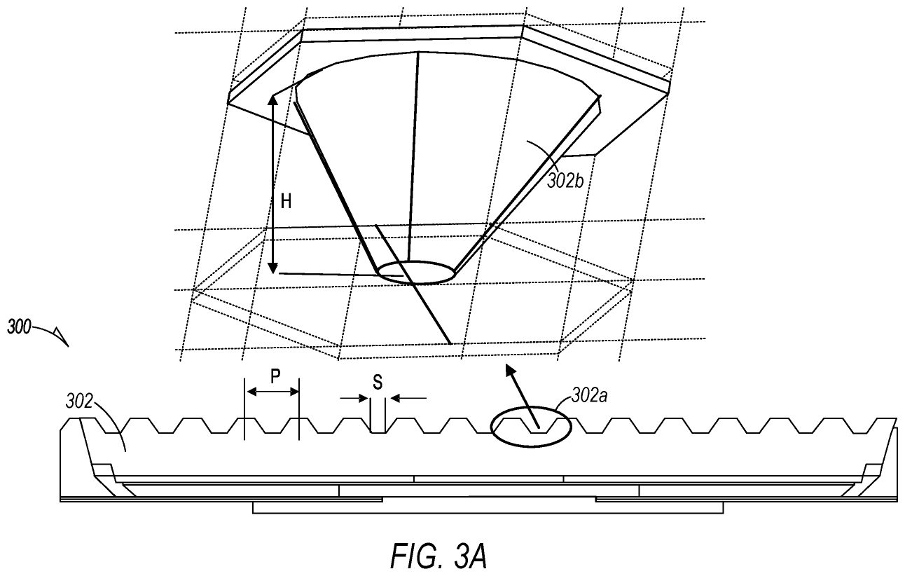

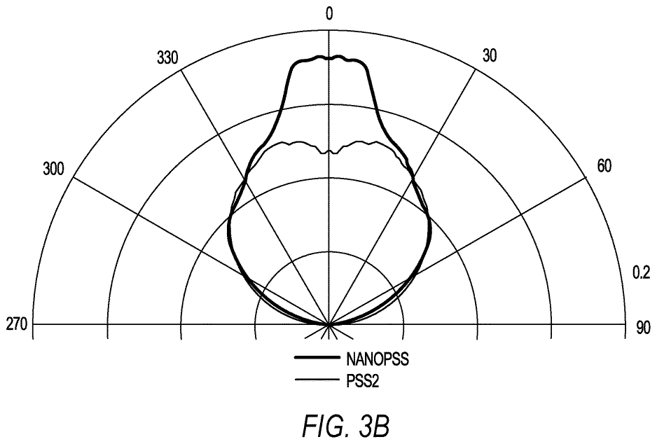

Thus, use of a nano-scale patterned sapphire substrate (nanoPSS) emitting surface may result in generating light with a narrow angular distribution, on-axis centered. After LLO the exposed nano-scale features on the GaN surface can efficiently steer the angular emission forward. FIG. 3A illustrates a single pixel of the monolithic LED pixel array of FIG. 2A, in accordance with some examples. As shown, the n-type semiconductor 302 of the single pixel 300 may have a nanoPSS emitting surface 302a with a regular pattern. As shown in the inset of FIG. 3A, the nanoPSS shape 302b may be substantially frustoconical. Typical nanoscale features may include periodic shapes with the following characteristics: a hexagonal lattice (based on the sapphire lattice structure), about 200 nm to about 500 nm pitch (P), about 200 nm to about 500 nm height (H), and about 20% spacing (S) (i.e., of the pitch).

Other shapes are, of course, possible as long as dimensions are kept within a few hundred nanometers.

FIG. 3B illustrates angular far-field radiation of microPSS and nanoPSS of the monolithic LED pixel array of FIG. 3A, in accordance with some examples. As shown, LEDs with a nanoPSS provide a narrower and stronger emission compared with LEDs with a microPSS (PSS2).

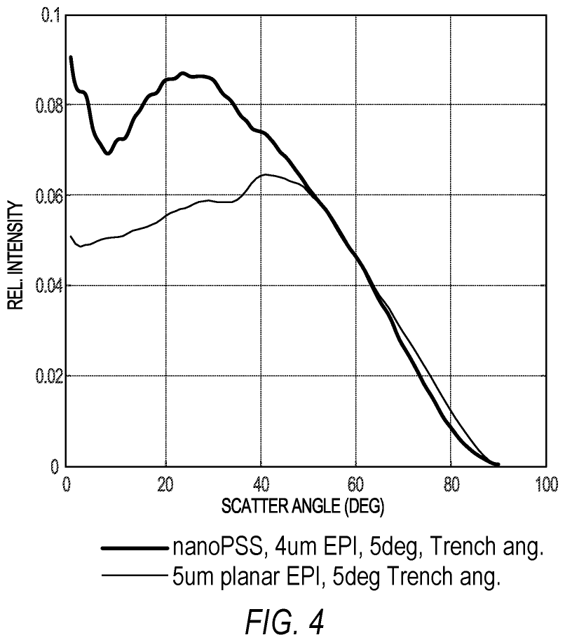

FIG. 4 illustrates far-field angular emission response, in accordance with some examples. In particular, FIG. 4 illustrates the simulated far-field angular emission response for 5 μm pixel sizes. As can be seen, LEDs with a nanoPSS can outperform LEDs with planar epitaxy for a 45° cone emission with trench sidewall angles of less than about 8°. For about a 5° trench angle (with respect to a normal angle from the emission surface), a 6% total flux improvement and 25% flux gain within the on-axis 45° cone may be achieved. The dimensions of the nanoPSS structures are about a 350 nm pitch and height.

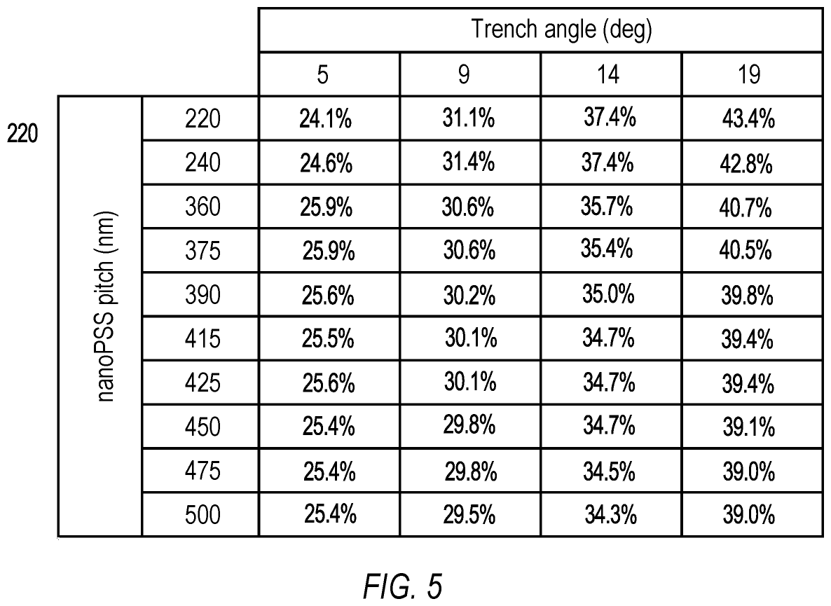

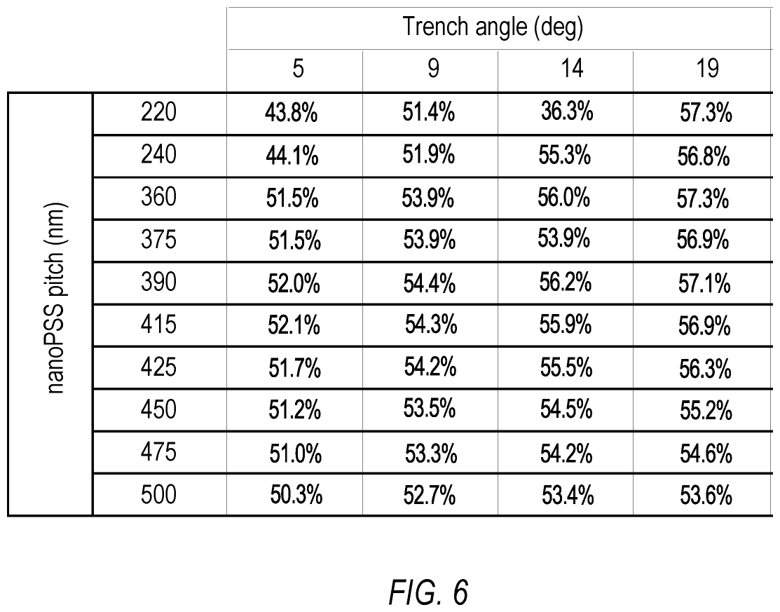

FIG. 5 illustrates simulated ExE for various nanoPSS designs, in accordance with some examples. FIG. 6 illustrates simulated forward emission gain for various nanoPSS designs, in accordance with some examples. The tables of FIGS. 5 and 6 illustrate an example in which the height of each of the nanoPSS features is equal to the pitch between the nanoPSS features, each nanoPSS structure has a substantially frustoconical shape, and the spacing is 20%. As is apparent, one optimal pitch of the nanoPSS features is about 350 nm to about 400 nm for steep trench angles (about 5° or less)—which gives rise to the largest simulated ExE in this angular range with a moderately high simulated forward emission. There may also be a tradeoff between the forward emission and ExE. Also FIGS. 5 and 6 show that for oblique trench angles, a small pitch/size may be preferred. An optimal pitch for ExE (regardless of the trench angle) may be less than about 400 nm. The size dependence on trench angle may be that an optimal pitch may reduce with increasing trench angle.

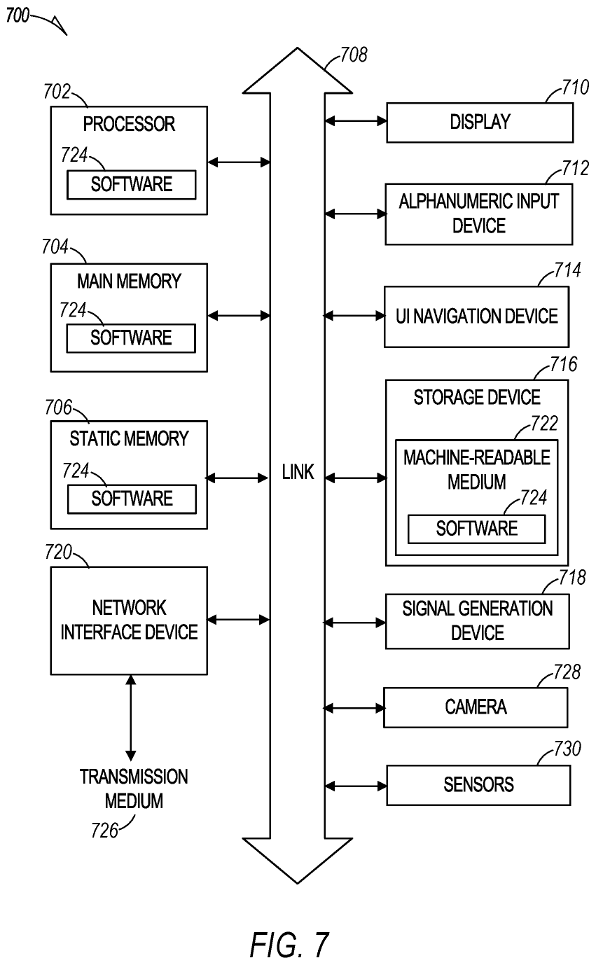

FIG. 7 illustrates an example of an electronic device in accordance with some embodiments. The electronic device 700 may be a mobile device such as a laptop computer (PC), a tablet PC, or a smart phone, for example, or a dedicated electronic apparatus, such as a camera, for example. Various elements may be provided on the PCB indicated above. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The mobile device 700 may include a hardware processor (or equivalently processing circuitry) 702 (e.g., a central processing unit (CPU), a GPU, a hardware processor core, or any combination thereof), a main memory 704 and a static memory 706, some or all of which may communicate with each other via an interlink (e.g., bus) 708. The main memory 704 may contain any or all of removable storage and non-removable storage, volatile memory or non-volatile memory. The mobile device 700 may further include a display 710 such as a video display, an alphanumeric input device 712 (e.g., a keyboard), and a user interface (UI) navigation device 714 (e.g., a mouse). In an example, the display 710, input device 712 and UI navigation device 714 may be a touch screen display. The mobile device 700 may additionally include a storage device (e.g., drive unit) 716, a signal generation device 718 (e.g., a speaker), a network interface device 720, one or more cameras 728, and one or more sensors 730, such as a global positioning system (GPS) sensor, compass, accelerometer, or other sensor such as those described herein. The mobile device 700 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 716 may include a non-transitory machine readable medium 722 (hereinafter simply referred to as machine readable medium) on which is stored one or more sets of data structures or instructions 724 (e.g., software) embodying or utilized by any one or more of the techniques or functions described herein. The non-transitory machine readable medium 722 is a tangible medium. A storage device 716 that includes the non-transitory machine-readable medium should not be construed as that either the device or the machine-readable medium is itself incapable of having physical movement. The instructions 724 may also reside, completely or at least partially, within the main memory 704, within static memory 706, and/or within the hardware processor 702 during execution thereof by the mobile device 700. While the machine readable medium 722 is illustrated as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the mobile device 700 and that cause the mobile device 700 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 724 may further be transmitted or received over a communications network using a transmission medium 726 via the network interface device 720 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5^{th} generation (5G) standards among others. In an example, the network interface device 720 may include one or more physical jacks (e.g., Ethernet, coaxial, or phone jacks) or one or more antennas to connect to the transmission medium 726.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

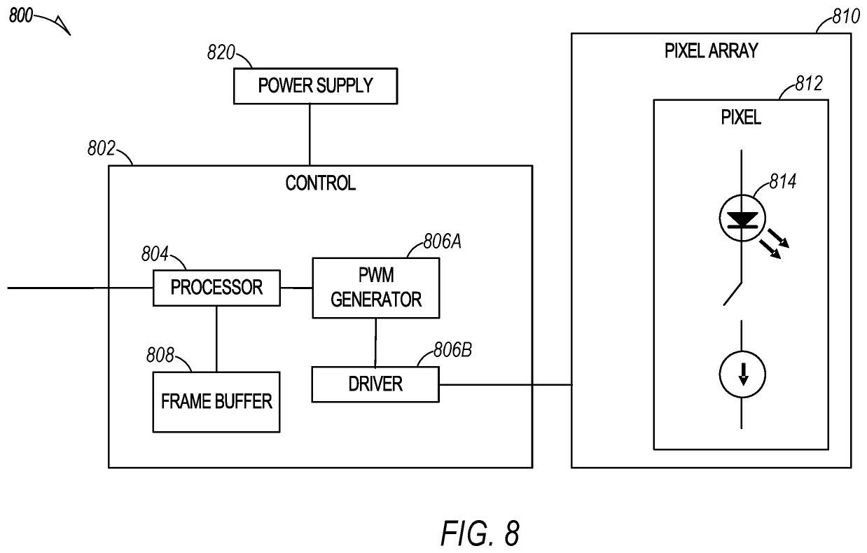

FIG. 8 illustrates an example lighting system, according to some embodiments. As above, some of the elements shown in the lighting system 800 may not be present, while other additional elements may be disposed in the lighting system 800. The lighting system 800 may provide lighting based on an image captured as described in FIG. 1 or may be independently generated based on stored information. For example, the lighting system 800 may include a controller 802 that controls display of an image using a pixel array 810 that contains multiple individual pixels 812.

In some embodiments, some or all of the components described as the controller 802 may be disposed on a backplane such as, for example, a compound metal oxide semiconductor (CMOS) backplane. The controller 802 may be coupled to or include one or more processors 804. The controller 802 may receive image data and inquiries from the one or more processors 804, if external to the controller 802. In this case, the controller 802 may further provide feedback to the one or more processors 804. The one or more processors 804 may receive image data via a digital interface and may process the image data to control a PWM generator 806a, for example, controlling PWM duty cycles and/or turn-on times for causing the lighting system 800 to produce the images indicated by the image data.

The controller 802 may further include a frame buffer 808. The frame buffer 808 may store one or more images prior the one or more processors 804 and store the indications for implementation by the one or more processors 804.

The PWM generator 806a may be controlled by the one or more processors 804 and may produce PWM signals in accordance with the indications. The PWM generator 806a may be connected to a driver 806b to drive the pixel array 810 so that the pixels 812 provide desired intensities of light.

Each pixel 812 may include one or more microLEDs 814. The microLEDs 814 may be different colors and may be controlled individually or in groups. As shown, the pixel 812 may include, for each pixel 812 or microLED 814, a PWM switch, and a current source. The pixel 812 may be driven by the driver 806b. The PWM signal from the PWM generator 806a may cause the PWM switch to open and close in accordance with the value of the PWM signal. The signal corresponding to the intensities of light may cause the current source to produce a current flow to cause the pixel 812 to produce the corresponding intensities of light.

The lighting system 800 may further include a power supply 820. In some embodiments, the power supply 820 may produce power for the controller 802.

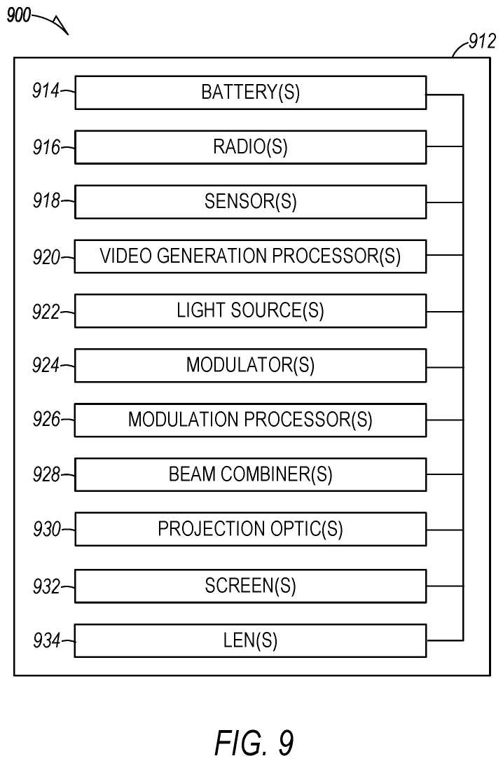

FIG. 9 shows a block diagram of an example of a system, according to some embodiments. The system 900 may provide augmented reality (AR)/virtual reality (VR) functionality using microLEDs. The system 900 can include a wearable housing 912, such as a headset or goggles. The housing 912 can mechanically support and house the elements detailed below. In some examples, one or more of the elements detailed below can be included in one or more additional housings that can be separate from the wearable housing 912 and couplable to the wearable housing 912 wirelessly and/or via a wired connection. For example, a separate housing can reduce the weight of wearable goggles, such as by including batteries, radios, and other elements. The housing 912 can include one or more batteries 914, which can electrically power any or all of the elements detailed below. The housing 912 can include circuitry that can electrically couple to an external power supply, such as a wall outlet, to recharge the batteries 914. The housing 912 can include one or more radios 916 to communicate wirelessly with a server or network via a suitable protocol, such as WiFi.

The system 900 can include one or more sensors 918, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 918 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 918 can capture a real-time video image of the surroundings proximate a user.

The system 900 can include one or more video generation processors 920. The one or more video generation processors 920 can receive scene data that represents a three-dimensional scene, such as a set of position coordinates for objects in the scene or a depth map of the scene. This data may be received from a server and/or a storage medium. The one or more video generation processors 920 can receive one or more sensor signals from the one or more sensors 918. In response to the scene data, which represents the surroundings, and at least one sensor signal, which represents the location and/or orientation of the user with respect to the surroundings, the one or more video generation processors 920 can generate at least one video signal that corresponds to a view of the scene. In some examples, the one or more video generation processors 920 can generate two video signals, one for each eye of the user, which represent a view of the scene from a point of view of the left eye and the right eye of the user, respectively. In some examples, the one or more video generation processors 920 can generate more than two video signals and combine the video signals to provide one video signal for both eyes, two video signals for the two eyes, or other combinations.

The system 900 can include one or more light sources 922 that can provide light for a display of the system 900. Suitable light sources 922 can include the microLEDs above, for example. The one or more light sources 922 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 900 can include one or more modulators 924. The modulators 924 can be implemented in one of at least two configurations. In a first configuration, the modulators 924 can include circuitry that can modulate the light sources 922 directly. For example, the light sources 922 can include an array of light-emitting diodes, and the modulators 924 can directly modulate the electrical power, electrical voltage, and/or electrical current directed to each light-emitting diode in the array to form modulated light. The modulation can be performed in an analog manner and/or a digital manner. In some examples, the light sources 922 can include an array of red light-emitting diodes, an array of green light-emitting diodes, and an array of blue light-emitting diodes, and the modulators 924 can directly modulate the red light-emitting diodes, the green light-emitting diodes, and the blue light-emitting diodes to form the modulated light to produce a specified image.

In a second configuration, the modulators 924 can include a modulation panel, such as a liquid crystal panel. The light sources 922 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 924 can include multiple modulation panels that can modulate different colors of light. For example, the modulators 924 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 924 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 900 can include one or more modulation processors 926, which can receive a video signal, such as from the one or more video generation processors 920, and, in response, can produce an electrical modulation signal. For configurations in which the modulators 924 directly modulate the light sources 922, the electrical modulation signal can drive the light sources 922. For configurations in which the modulators 924 include a modulation panel, the electrical modulation signal can drive the modulation panel.

The system 900 can include one or more beam combiners 928 (also known as beam splitters), which can combine light beams of different colors to form a single multi-color beam. For configurations in which the light sources 922 can include multiple light-emitting diodes of different colors, the system 900 can include one or more wavelength-sensitive (e.g., dichroic) beam combiners 928 that can combine the light of different colors to form a single multi-color beam.

The system 900 can direct the modulated light toward the eyes of the viewer in one of at least two configurations. In a first configuration, the system 900 can function as a projector, and can include suitable projection optics 930 that can project the modulated light onto one or more screens 932. The screens 932 can be located a suitable distance from an eye of the user. The system 900 can optionally include one or more lenses 934 that can locate a virtual image of a screen 932 at a suitable distance from the eye, such as a close-focus distance, such as 500 mm, 750 mm, or another suitable distance. In some examples, the visualization system 910 can include a single screen 932, such that the modulated light can be directed toward both eyes of the user. In some examples, the system 900 can include two screens 932, such that the modulated light from each screen 932 can be directed toward a respective eye of the user. In some examples, the system 900 can include more than two screens 932. In a second configuration, the system 900 can direct the modulated light directly into one or both eyes of a viewer. For example, the projection optics 930 can form an image on a retina of an eye of the user, or an image on each retina of the two eyes of the user.

For some configurations of AR systems, the system 900 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

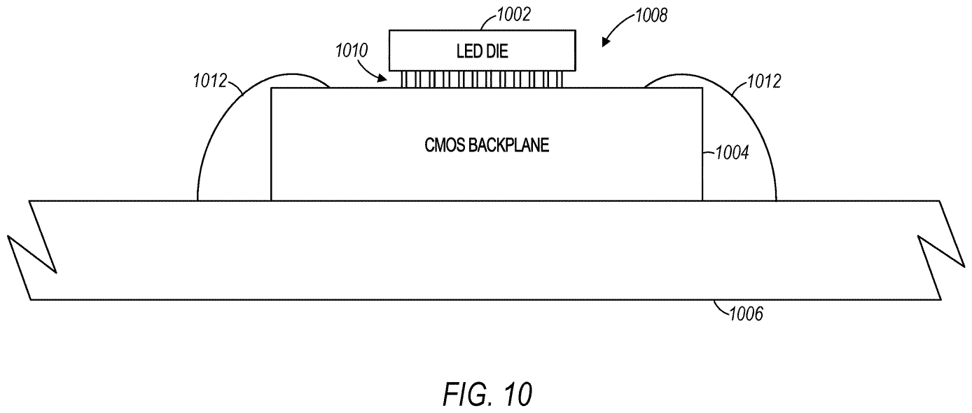

FIG. 10 illustrates an example hardware arrangement for implementing the above disclosed subject matter, according to some embodiments. In particular, the hardware arrangement 1000 may include an integrated LED 1008. The integrated LED 1008 may include an LED die 1002 that contains the microLED array(s) and a backplane, such as a CMOS backplane 1004. The LED die 1002 may be coupled to the CMOS backplane 1004 by one or more interconnects 1010, where the interconnects 1010 may provide for transmission of signals between the LED die 1002 and the CMOS backplane 1004. The interconnects 1010 may comprise one or more solder bump joints, one or more copper pillar bump joints, other types of interconnects known in the art, or some combination thereof.

The LED die 1002 may include circuitry to implement the micro-LED array. In particular, the LED die 1002 may include a plurality of micro-LEDs. The LED die 1002 may include a shared active layer and a shared substrate for the micro-LED array, and thereby the micro-LED array may be a monolithic micro-LED array. Each micro-LED of the micro-LED array may include an individual segmented active layer and/or substrate. In some embodiments, the LED die 1002 may further include switches and current sources to drive the micro-LED array. In other embodiments, the PWM switches and the current sources may be included in the CMOS backplane 1004.

The CMOS backplane 1004 may include circuitry to implement the control module and/or the LED power supply. The CMOS backplane 1004 may utilize the interconnects 1010 to provide the micro-LED array with the PWM signals and the signals for the intensity for causing the micro-LED array to produce light in accordance with the PWM signals and the intensity. Because of the relatively large number and density of connections to drive the micro-LED array compared to standard LED arrays, different embodiments may be used to electrically connect the CMOS backplane 1004 and the LED die 1002. Either the bonding pad pitch of the CMOS backplane 1004 may be the same as the pitch of bonding pads in the micro-LED array, or the bonding pad pitch of the CMOS backplane 1004 may be larger than the pitch of bonding pads in the micro-LED array.

The hardware arrangement 1000 may further include a PCB 1006. The PCB 1006 may include circuitry to implement various functionality described herein. The PCB 1006 may be coupled to the CMOS backplane 1004. For example, the PCB 1006 may be coupled to the CMOS backplane 1004 via one or more wire bonds 1012. The PCB 1006 and the CMOS backplane 1004 may exchange image data, power, and/or feedback via the coupling, among other signals.

As shown, the micro-LEDs and circuitry supporting the micro-LED array can be packaged and include a submount or printed circuit board for powering and controlling light production by the micro-LEDs. The PCB 1006 supporting the micro-LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the micro-LED array and a power supply, and also provide heat sink functionality.

As above, a variety of applications may be supported by micro-LED arrays. Such applications may include a stand-alone application to provide general illumination (e.g., within a room or vehicle) or to provide specific images. In addition to devices such as a luminaire, projector, mobile device, the system may be used to provide either augmented reality (AR) and virtual reality (VR)-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more micro-LED pixels (groups of micro-LEDs) to display content (AR/VR and/or non-AR/VR) to the user while controlling other micro-LEDs and sensors used in eye tracking to adjust the content displayed. Content display micro-LEDs may be designed to emit light within the visible band (approximately 400 nm to 780 nm) while micro-LEDs used for tracking may be designed to emit light in the IR band (approximately 780 nm to 2,200 nm). In some embodiments, the tracking micro-LEDs and content micro-LEDs may be simultaneously active. In some embodiments, the tracking micro-LEDs may be controlled to emit tracking light during a time period that content micro-LEDs are deactivated and are thus not displaying content to the user. The AR/VR system can incorporate optics, such as those described above, and/or an AR/VR display, for example to couple light emitted by micro-LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

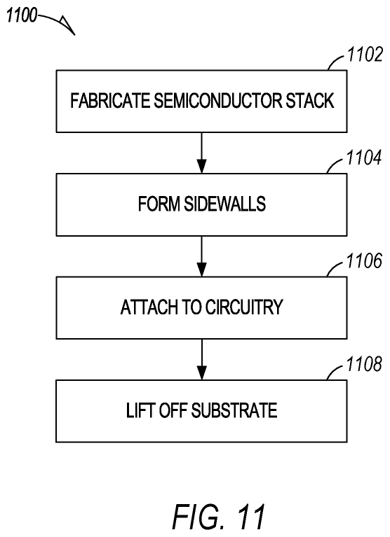

FIG. 11 illustrates an example method of fabricating an LED device, according to some embodiments. Not all of the operations may be undertaken in the method 1100, and/or additional operations may be present.

At operation 1102, the semiconductor stack to form the microLEDs may be deposited on a sapphire or other substrate having a nanoPSS structure. For a GaN-based multilayer semiconductor stack, hydride vapor phase epitaxy (HVPE) may be used, for example. For other compound semiconductors, Metalorganic vapor-phase epitaxy (MOCVD) or Molecular beam epitaxy (MBE), for example, may be used to fabricate the semiconductor stack. The semiconductor stack may contain a quantum well active region, for example, which emits light. The emitting surface of the semiconductor stack, which is in contact with the substrate, may have nanoPSS features.

After fabrication of the semiconductor stack, the sidewalls may be formed at operation 1104. To form the sidewalls, each layer in the semiconductor stack may be sequentially etched to form a via using photolithographic processes, and the metal deposited in the via before stripping the photoresist. The sidewalls may be formed from aluminum or another material that is substantially reflective (e.g., greater than about 99% reflectivity at a normal angle of incidence) to light emitted by the semiconductor stack. The sidewalls may direct light to the emitting surface of the semiconductor stack.

The overall structure may be attached to a PCB or other wafer at operation 1106. Flip-chip or ball bonding, for example, may be used to electrically connect the microLEDs to the circuitry.

The substrate may be lifted off from the semiconductor stack at operation 1108 exposing the emitting surface, which contains the nanoPSS features.

The semiconductor stack (and thus trench height) may be, for example, about 4 μm to about 6 μm thick. This permits the n-type semiconductor that contacts the substrate with the nanoPSS structure sufficient structural integrity to form a regular periodic semiconductor lattice structure for the active regions. In other embodiments, to reduce the aspect ratio of the microLED, the epitaxial n-type semiconductor may be etched after liftoff of the substrate to a thinner layer (e.g., about 1 μm to about 2 μm). Thus, in this embodiment, the substrate may or may not have a nanoPSS structure.

Regardless of whether the substrate has a nanoPSS structure, however, the epitaxial n-type semiconductor may be etched to form either a substantially planar surface or a nanoPSS structure (that contains the nanoPSS features described herein). In the former case, the nanoPSS structure may be formed by depositing a dielectric layer (e.g., titanium oxide (TiO2)) and processing the dielectric layer by etching and other lithographic techniques. In the latter case, the nanoPSS structure may be formed by nanopatterning (nanoimprinting) the surface of the thin film epitaxial n-type semiconductor by various etching techniques. In either case, the metal-semiconductor n-contact may accordingly be formed on the sidewalls of the trench.

Another embodiment may use a substantially transparent film to the light from the microLED. The transparent film may be a transparent conductive oxide (TCO) such as indium tin oxide (ITO). In such an embodiment, the nanoPSS structure may be patterned on the surface of a blanket TCO layer deposited on top of the thin film epitaxial n-type semiconductor extending over the trench metal regions, thus forming a top n-contact. Patterned features may be formed by etching a thin dielectric layer (e.g., TiO2, as above), which may be patterned by etching and other lithographic techniques. In this case, the trench sidewalls may be fully coated with the dielectric (e.g., in FIG. 2C, the oxide layer 226 may extend all the way through the trench side walls), which may be optically more efficient than the use of lateral sidewall contacts at the trench.

More details about the patterning of the thin film epitaxial semiconductor, the oxide layer, or the transparent film may be found in U.S. Pat. No. 10,090,437, herein incorporated by reference in its entirety.

### EXAMPLES

Example 1 is a micro light-emitting diode (microLED) structure comprising: a microLED comprising a semiconductor stack that includes, an n-type semiconductor, a p-type semiconductor, and an active region sandwiched between the n-type semiconductor and the p-type semiconductor, the microLED having an emitting surface from which light generated by the active region exits the microLED, the emitting surface having nanoscale patterned sapphire substrate (nanoPSS) features therein; and metal sidewalls extending from the emitting surface of the n-type semiconductor to the p-type semiconductor and configured to electrically couple to the n-type semiconductor, the metal sidewalls forming a trench in which the microLED is disposed, the metal sidewalls being substantially reflective to the light generated by the active region.

In Example 2, the subject matter of Example 1 includes, wherein the nanoPSS features comprise periodic shapes each having a hexagonal lattice and being less than about 1 μm.

In Example 3, the subject matter of Example 2 includes, wherein the periodic shapes have a pitch of about 200 nm to about 500 nm, a height of about 200 nm to about 500 nm, and a spacing of about 20%.

In Example 4, the subject matter of Example 3 includes, wherein the pitch and the height are substantially identical.

In Example 5, the subject matter of Examples 2-4 includes, wherein each periodic shape is frustoconical.

In Example 6, the subject matter of Examples 1-5 includes, wherein: the metal sidewalls extend at a trench angle with respect to a normal to the emitting surface, and the trench angle is less than about 9%, and the nanoPSS features comprise periodic shapes having a pitch of about 350 nm to about 400 nm, a height of about 350 nm to about 400 nm, and a spacing of about 20%.

In Example 7, the subject matter of Examples 1-6 includes, wherein a trench height of the trench is about 4 μm to about 6 μm.

In Example 8, the subject matter of Examples 1-7 includes, wherein the n-type semiconductor is an etched n-type semiconductor, the semiconductor stack having a trench height of about 1 μm to about 2 μm.

In Example 9, the subject matter of Examples 1-8 includes, wherein a surface of the n-type semiconductor includes the nanoPSS features.

In Example 10, the subject matter of Examples 1-9 includes, wherein the microLED further comprises a substantially transparent film disposed on the n-type semiconductor, the n-type semiconductor being substantially planar, the substantially transparent film having the nanoPSS features.

Example 11 is an illumination device comprising: a micro light-emitting diode (microLED) structure comprising a microLED containing a semiconductor stack that includes, an n-type semiconductor, a p-type semiconductor, and an active region sandwiched between the n-type semiconductor and the p-type semiconductor, the microLED having an emitting surface from which light generated by the active region exits the microLED, the emitting surface having nanoscale patterned sapphire substrate (nanoPSS) features therein; and a backplane to which the microLED structure is attached, the backplane containing control circuitry to control light emission from the microLED.

In Example 12, the subject matter of Example 11 includes, wherein the nanoPSS features comprise periodic frustoconical shapes that are less than about 1 μm and each frustoconical shape has a hexagonal lattice.

In Example 13, the subject matter of Example 12 includes, wherein the periodic shapes have a pitch of about 200 nm to about 500 nm, a height of about 200 nm to about 500 nm, and a spacing of about 20%.

In Example 14, the subject matter of Example 13 includes, wherein the pitch and the height are substantially identical.

In Example 15, the subject matter of Examples 11-14 includes, wherein: the microLED structure further comprises: metal sidewalls extending from the emitting surface of the n-type semiconductor to the p-type semiconductor and configured to electrically contact the n-type semiconductor, and an insulating layer disposed between the metal sidewalls and both the p-type semiconductor and the active region, the metal sidewalls form a trench in which the microLED is disposed, the metal sidewalls are substantially reflective to the light generated by the active region, and the metal sidewalls extend at a trench angle with respect to a normal to the emitting surface.

In Example 16, the subject matter of Example 15 includes, wherein: the trench angle is less than about 9%, the nanoPSS features are formed in the n-type semiconductor and comprise periodic frustoconical shapes having a pitch of about 350 nm to about 400 nm, a height of about 350 nm to about 400 nm, and a spacing of about 20%, and a trench height of the trench is about 4 μm to about 6 μm

In Example 17, the subject matter of Examples 11-16 includes, wherein a surface of the n-type semiconductor includes the nanoPSS features.

In Example 18, the subject matter of Examples 11-17 includes, wherein: the microLED further comprises a substantially transparent film disposed on the n-type semiconductor, the n-type semiconductor is substantially planar, and the substantially transparent film has the nanoPSS features.

Example 19 is a method of fabricating an illumination device, the method comprising: epitaxially growing, on a substrate, a semiconductor stack that includes, an n-type semiconductor, a p-type semiconductor, and an active region sandwiched between the n-type semiconductor and the p-type semiconductor; and fabricating a micro-light-emitting diode (microLED) containing the semiconductor stack such that the microLED has an emitting surface from which light generated by the active region exits the microLED, the emitting surface having nanoscale patterned sapphire substrate (nanoPSS) features therein.

In Example 20, the subject matter of Example 19 includes, wherein the nanoPSS features comprise periodic frustoconical shapes that are less than about 1 μm and each frustoconical shape has a hexagonal lattice.

In Example 21, the subject matter of Example 20 includes, wherein the periodic shapes have a pitch of about 200 nm to about 500 nm, a height of about 200 nm to about 500 nm, and a spacing of about 20%.

In Example 22, the subject matter of Example 21 includes, wherein the pitch and the height are substantially identical.

In Example 23, the subject matter of Examples 19-22 includes, wherein fabricating the microLED further comprises: depositing an insulating layer on the p-type semiconductor and the active region to form a partially insulated structure, and depositing metal sidewalls on the partially insulated structure and the n-type semiconductor to electrically contact the n-type semiconductor, the metal sidewalls forming a trench in which the microLED is disposed, the metal sidewalls being substantially reflective to the light generated by the active region, the metal sidewalls extending at a trench angle with respect to a normal to the emitting surface.

In Example 24, the subject matter of Example 23 includes, wherein: the trench angle is less than about 9%, the nanoPSS features are formed in the n-type semiconductor and comprise periodic frustoconical shapes having a pitch of about 350 nm to about 400 nm, a height of about 350 nm to about 400 nm, and a spacing of about 20%, and a trench height of the trench is about 4 um to about 6 μm

In Example 25, the subject matter of Examples 19-24 includes, wherein fabricating the microLED further comprises: lifting off the substrate from the semiconductor stack to expose a top surface of the n-type semiconductor; etching the top surface of the n-type semiconductor to form a planar top surface and to reduce a height of the n-type semiconductor to less than about 2 μm; depositing a substantially transparent film on the planar top surface of the n-type semiconductor; and patterning the substantially transparent film to have the nanoPSS features.

In Example 26, the subject matter of Examples 19-25 includes, attaching the microLED to a backplane containing control circuitry to control light emission from the microLED.

Example 27 is at least one machine-readable medium including instructions that, when executed by processing circuitry, cause the processing circuitry to perform operations to implement of any of Examples 1-26.

Example 28 is an apparatus comprising means to implement of any of Examples 1-26.

Example 29 is a system to implement of any of Examples 1-26.

Example 30 is a method to implement of any of Examples 1-26.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A micro light-emitting diode (microLED) structure comprising:
a microLED comprising a semiconductor stack that includes an n-type semiconductor, a p-type semiconductor, and an active region sandwiched between the n-type semiconductor and the p-type semiconductor, the microLED having an emitting surface from which light generated by the active region exits the microLED, the emitting surface having nanoscale patterned sapphire substrate (nanoPSS) features therein; and
metal sidewalls extending from the emitting surface of the n-type semiconductor to the p-type semiconductor and configured to electrically couple to the n-type semiconductor, the metal sidewalls forming a trench in which the microLED is disposed, the metal sidewalls being substantially reflective to the light generated by the active region.

2. The microLED structure of claim 1, wherein the nanoPSS features comprise periodic shapes each having a hexagonal lattice and being less than about 1 μm.

3. The microLED structure of claim 2, wherein the periodic shapes have a pitch of about 200 nm to about 500 nm, a height of about 200 nm to about 500 nm, and a spacing of about 20%.

4. The microLED structure of claim 3, wherein the pitch and the height are substantially identical.

5. The microLED structure of claim 2, wherein each periodic shape is frustoconical.

6. The microLED structure of claim 1, wherein:
the metal sidewalls extend at a trench angle with respect to a normal to the emitting surface, and
the trench angle is less than about 9%, and the nanoPSS features comprise periodic shapes having a pitch of about 350 nm to about 400 nm, a height of about 350 nm to about 400 nm, and a spacing of about 20%.

7. The microLED structure of claim 1, wherein a trench height of the trench is about 4 μm to about 6 μm.

8. The microLED structure of claim 1, wherein the n-type semiconductor is an etched n-type semiconductor, the semiconductor stack having a trench height of about 1 μm to about 2 μm.

9. The microLED structure of claim 1, wherein a surface of the n-type semiconductor includes the nanoPSS features.

10. The microLED structure of claim 1, wherein the microLED further comprises a substantially transparent film disposed on the n-type semiconductor, a surface of the n-type semiconductor opposing the substantially transparent film being substantially planar, the substantially transparent film having the nanoPSS features.

11. An illumination device comprising:
a micro light-emitting diode (microLED) structure comprising a microLED containing a semiconductor stack that includes an n-type semiconductor, a p-type semiconductor, and an active region sandwiched between the n-type semiconductor and the p-type semiconductor, the microLED having an emitting surface from which light generated by the active region exits the microLED, the emitting surface having nanoscale patterned sapphire substrate (nanoPSS) features therein; and
a backplane to which the microLED structure is attached, the backplane containing control circuitry to control light emission from the microLED.

12. The illumination device of claim 11, wherein the nanoPSS features comprise periodic frustoconical shapes that are less than about 1 μm and each periodic frustoconical shape has a hexagonal lattice.

13. The illumination device of claim 12, wherein the periodic frustoconical shapes have a pitch of about 200 nm to about 500 nm, a height of about 200 nm to about 500 nm, and a spacing of about 20%.

14. The illumination device of claim 13, wherein the pitch and the height are substantially identical.

15. The illumination device of claim 11, wherein:
the microLED structure further comprises:
metal sidewalls extending from the emitting surface of the n-type semiconductor to the p-type semiconductor and configured to electrically contact the n-type semiconductor, and
an insulating layer disposed between the metal sidewalls and both the p-type semiconductor and the active region,
the metal sidewalls form a trench in which the microLED is disposed,
the metal sidewalls are substantially reflective to the light generated by the active region, and
the metal sidewalls extend at a trench angle with respect to a normal to the emitting surface.

16. The illumination device of claim 15, wherein:
the trench angle is less than about 9%,
the nanoPSS features are formed in the n-type semiconductor and comprise periodic frustoconical shapes having a pitch of about 350 nm to about 400 nm, a height of about 350 nm to about 400 nm, and a spacing of about 20%, and
a trench height of the trench is about 4 μm to about 6 μm.

17. The illumination device of claim 11, wherein the microLED structure further comprises a substantially transparent film disposed on the n-type semiconductor, a surface of the n-type semiconductor opposing the substantially transparent film being substantially planar, the substantially transparent film having the nanoPSS features.

18. The illumination device of claim 11, wherein:
the microLED further comprises a substantially transparent film disposed on the n-type semiconductor,
the n-type semiconductor is substantially planar, and
the substantially transparent film has the nanoPSS features.

19. A method of fabricating an illumination device, the method comprising:
epitaxially growing, on a substrate, a semiconductor stack that includes an n-type semiconductor, a p-type semiconductor, and an active region sandwiched between the n-type semiconductor and the p-type semiconductor; and
fabricating a micro-light-emitting diode (microLED) containing the semiconductor stack such that the microLED has an emitting surface from which light generated by the active region exits the microLED, the emitting surface having nanoscale patterned sapphire substrate (nanoPSS) features therein.

20. The method of claim 19, wherein fabricating the microLED further comprises:
lifting off the substrate from the semiconductor stack to expose a top surface of the n-type semiconductor;
etching the top surface of the n-type semiconductor to form a planar top surface and to reduce a height of the n-type semiconductor to less than about 2 μm;
depositing a substantially transparent film on the planar top surface of the n-type semiconductor; and
patterning the substantially transparent film to have the nanoPSS features.
